(19) United States
(12) Patent Application Publication
(10) Pub. No.: US 2007/0075771 A1
(43) Pub. Date: Apr. 5, 2007

(54) ANTI-THEFT STRUCTURE FOR MOBILE PHONE

(75) Inventors: Yu-Hsu Lin, San Jose, CA (US); Xiang Cao, Shenzhen (CN); Ke-You Hu, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,272

(22) Filed: Jul. 21, 2006

(30) Foreign Application Priority Data
Sep. 21, 2005 (CN) 200510037461.7

(51) Int. Cl. H03F 3/04

(52) U.S. Cl. 330/250

(57) ABSTRACT

An anti-theft structure for a mobile phone, the anti-theft structure includes a power device for providing a direct current (DC) voltage, an oscillator circuit receiving the DC voltage and producing an oscillating signal, an amplifying element being connected to the oscillator circuit to amplifying the oscillating signal and producing a high-voltage oscillating signal, and a power amplifying circuit being connected to the amplifying element for amplifying power of the high-voltage oscillating signal and producing a high voltage arc at an output terminal of the power amplifying circuit.

### FIELD OF THE INVENTION

The invention relates to an anti-theft structure for a mobile phone, more particularly to an anti-theft structure for preventing a mobile phone from being stolen.

### DESCRIPTION OF RELATED ART

Mobile phones have been identified as CRAVED (Concealable, Removable, Available, Valuable, Enjoyable, Disposable) items that are highly attractive to thieves and this will be exacerbated as phones become more sophisticated and start to offer users advanced functionality, such as the ability to pay for goods and services directly through the handset. If criminal steal the mobile phone it creates a lot of trouble for the victim and is a financial burden.

A conventional method for preventing a mobile phone from being stolen is to set an alarm circuit on a protecting sheath, which holds the mobile phone. One such method is disclosed in Chinese Pat. No. 03202999.3, wherein a hanging clip is set on a protecting sheath of a mobile phone, the hanging clip includes a latch, a button, and an alarm circuit. The latch is used to securely close the protecting sheath. When the protecting sheath is not opened in a proper way, the latch actuates the button to turn on the alarm circuit to produce an alarm, which may help prevent the mobile phone from being stolen.

However, it is not convenient to use the mobile phone because the mobile phone is not usable in the protecting sheath and it is unprotected when removed from the protecting sheath for use.

What is needed is an anti-theft structure for a mobile phone that prevents the mobile phone from being stolen and is still convenient to use.

### SUMMARY OF THE INVENTION

An exemplary anti-theft structure for a mobile phone includes a power device for providing a direct current (DC) voltage, an oscillator circuit receiving the DC voltage and producing an oscillating signal, an amplifying element being connected to the oscillator circuit to amplify the oscillating signal producing a high-voltage oscillating signal, and a power amplifying circuit being connected to the amplifying element for amplifying power of the high-voltage oscillating signal and producing a high voltage arc at an output terminal of the power amplifying circuit.

Other advantages and novel features will become more apparent from the following detailed description when taken in conjunction with the accompanying drawing, in which:

### BRIEF DESCRIPTION OF THE DRAWINGS

FIG. 1 is a block diagram of an anti-theft structure for a mobile phone in accordance with a preferred embodiment of the present invention; and

FIG. 2 is a circuit diagram of the anti-theft structure for a mobile phone of FIG. 1.

### DETAILED DESCRIPTION OF THE INVENTION

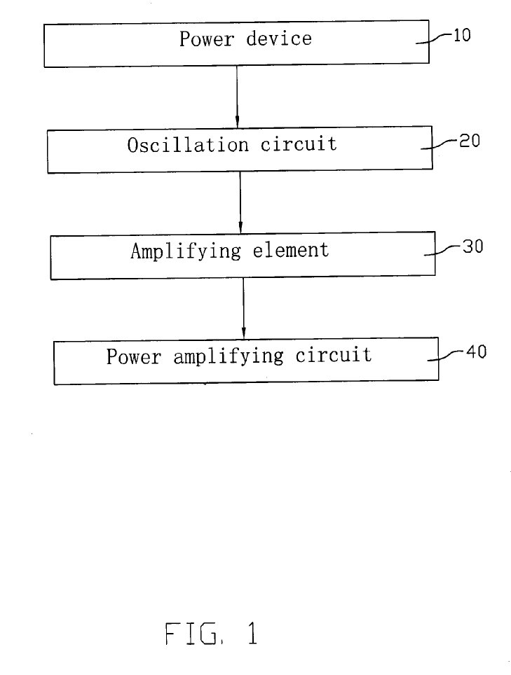

Referring to FIG. 1, an anti-theft structure for a mobile phone in accordance with a preferred embodiment of the present invention includes a power device 10, an oscillator circuit 20, an amplifying element 30, and a power amplifying circuit 40.

The power device 10 is used to supply a direct current (DC) voltage to the oscillator circuit 20. The oscillator circuit 20 generates an oscillating signal in response to the DC voltage. The oscillating signal is provided to the amplifying element 30 to produce a high-voltage signal. The high-voltage signal is provided to the power amplifying circuit 40 for amplifying the power of the high-voltage signal.

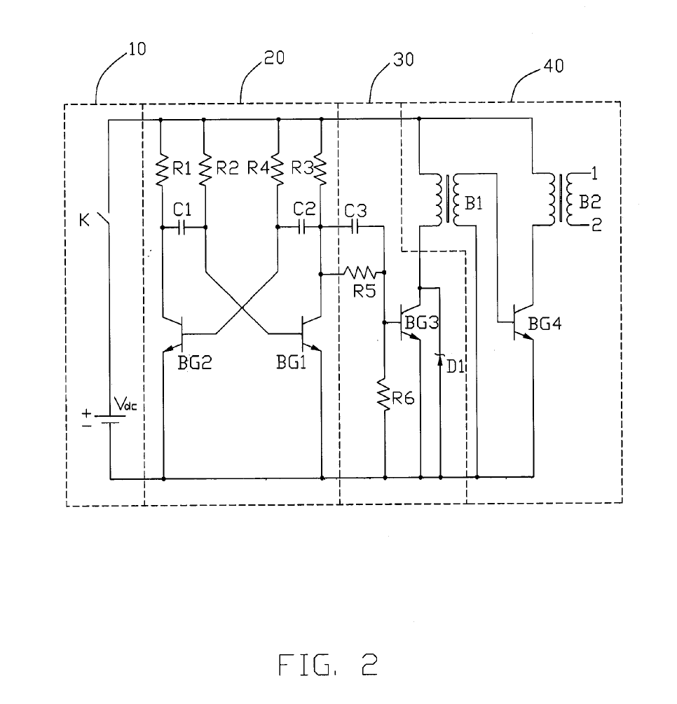

Refers to FIG. 2, the power device 10 includes a DC power source Vdc and a switch K. The DC power source Vdc can be a battery that powers the mobile phone or a separate DC battery set in the mobile phone specifically for use in powering the anti-theft structure. A first terminal of the switch K is connected to positive terminal of the DC power source Vdc.

The oscillator circuit 20 is an astable multivibrator circuit, which is known in the art and thus will be only briefly described. A second terminal of the switch K is connected to a base of a first NPN transistor BG1 through a first resistor R1 and a first capacitor C1 which are in parallel with a second resistor R2. Likewise, the second terminal of the switch K is connected to a base of a second NPN transistor BG2 through a third resistor R3 and a second capacitor C2 which are in parallel with a fourth resistor R4. An emitter of the transistor BG1 is connected to a negative terminal of the DC power source Vdc and a collector of the transistor BG1 is connected to a junction of the resistor R3 and capacitor C2. An emitter of the transistor BG2 is connected to the negative terminal of the DC power source Vdc and a collector of the transistor BG2 is connected to a junction of the resistor R1 and the capacitor C1.

The amplifying element 30 includes a third NPN transistor BG3. A base of the transistor BG3 is connected to the collector of the transistor BG1 through a third capacitor C3 that is in parallel with a fifth resistor R5. The base of the transistor BG3 is connected to the negative terminal of the DC power source Vdc through a sixth resistor R6. An emitter of the transistor BG3 is connected to the negative terminal of the DC power source Vdc and a collector of the transistor BG3 is connected to the negative terminal of the DC power source Vdc through a zener diode D1.

The power amplifying circuit 40 includes a first transformer B1, a second transformer B2, and a fourth NPN transistor BG4. A first terminal of a primary coil of the first transformer B1 is connected to the collector of the transistor BG3 and a second terminal of the primary coil of B1 is connected to the second terminal of the switch K. A first terminal of a secondary coil of B1 is connected to the negative terminal of the DC power source Vdc and a second terminal of the secondary coil of B1 is connected to a base of the transistor BG4. A first terminal of a primary coil of the transformer B2 is connected to a collector of the transistor BG4 and a second terminal of the primary coil of B2 is connected to the second terminal of the switch K. An emitter of the transistor BG4 is connected to the negative terminal of the DC power source Vdc.

When the switch K is on, a constant DC voltage from the DC power source Vdc is provided to the oscillator circuit 20. The first and second transistors BG2 and BG3 are alternatively turned on and off to generate the oscillating signal at the transistor BG1 with a time period which is defined by resistance of the resistors R2 and R4 and capacitance of the capacitors C1 and C2. In this embodiment, the resistances of the resistors R2 and R4 are greater than those of the resistors R1 and R3.

The oscillating signal is coupled to the base of the transistor BG3 through the capacitor C3. The resistors R3, R5, and R6 are in series to provide a bias voltage to the base of the transistor BG3 to ensure the transistor BG3 is working in the amplifying region. The transistor BG3 amplifies the oscillating signal to a high-voltage signal, which is then coupled to the base of the transistor BG4 through the first transformer B1 for amplifying power of the high-voltage signal. The amplified high-voltage signal then goes to the second transformer B2, which is a step-up transformer, at which time a high voltage arc is produced at first and second terminals 1, 2 of the secondary coil of the transformer B2.

The anti-theft structure is set in a mobile phone, and a button (not shown) is defined in a profile plane of the mobile phone corresponding to the switch K. When the button is pressed down the switch K is turned on and when the button is released the switch K is turned off. Two electrode bars (not shown), connected to the first and second terminals 1, 2 of the secondary coil of the transformer B2, protrude from a front portion of the mobile phone. When a criminal attempts to steal the mobile phone, a user aims the two electrode bars of the mobile phone toward the criminal, and then presses down the button, causing a high voltage arc to be produced at the two electrode bars, for deterring the criminal from attacking, and from stealing the mobile phone. Releasing the button stops production of the high-voltage arc.

It is believed that the present embodiment and its advantage will be understood from the foregoing description, and it will be apparent that various changes may be made thereto without departing from the spirit and scope of the invention or sacrificing all of its material advantages, the example hereinbefore described merely being preferred or exemplary embodiment.

What is claimed is:

1. An anti-theft structure for a mobile phone, the anti-theft structure comprising:
a power device for providing a direct current (DC) voltage;
an oscillator circuit receiving the DC voltage and producing an oscillating signal;
an amplifying element being connected to the oscillator circuit to amplifying the oscillating signal and producing a high-voltage signal; and
a power amplifying circuit being connected to the amplifying element for amplifying power of the high-voltage signal and producing a high-voltage arc at an output terminal of the power amplifying circuit.

2. The anti-theft structure as claimed in claim 1, wherein the power device includes a DC power source and a switch, the switch controls the DC power source to provide the DC voltage to the oscillator circuit.

3. The anti-theft structure as claimed in claim 2, wherein the oscillator circuit is an astable multivibrator circuit, when the DC voltage is provided to the astable multivibrator circuit, the oscillating signal is produced at an output terminal thereof.

4. The anti-theft structure as claimed in claim 3, wherein the amplifying element includes a first transistor for amplifying the oscillating signal and producing the high-voltage signal.

5. The anti-theft structure as claimed in claim 4, wherein the power amplifying circuit includes a first transformer, a second transformer, and a second transistor, the high-voltage signal is coupled to a base of the second transistor through the first transformer, the second transformer is connected to a collector of the second transistor.

6. The anti-theft structure as claimed in claim 5, wherein a button is defined in a profile plane of the mobile phone corresponding to the switch, two electrode bars are connected to terminals of a secondary coil of the second transformer and protrude form a front portion of the mobile phone, when the button is pressed down the high voltage arc is produced at the two electrode bars.

7. An anti-theft structure for using in a mobile phone, the anti-theft structure comprising:
a power device for providing a direct current (DC) voltage controlled by a switch;
a button is defined in a profile plane of the mobile phone corresponding to the switch;
a first means for producing an oscillating signal in response to the DC voltage;
a second means for amplifying the oscillating signal and producing a high-voltage arc at its output terminal; and
two electrode bars leading out from the output terminal of the second means.

8. The anti-theft structure as claimed in claim 7, wherein when the button is pressed down the high-voltage arc is produced at the two electrode bars.

9. The anti-theft structure as claimed in claim 7, wherein the first means is an astable multivibrator circuit, when the DC voltage is provided to the astable multivibrator circuit the oscillating signal is produced at its output terminal.

10. The anti-theft structure as claimed in claim 7, wherein the second means includes an amplifying element and a power amplifying circuit, the amplifying element is connected to the first means to amplify the oscillating signal and produce a high-voltage signal, the power amplifying circuit is connected to the amplifying device for amplifying power of the high-voltage signal and the high voltage arc is produced at an output terminal of the power amplifying circuit.

11. The anti-theft structure as claimed in claim 10, wherein the amplifying element includes a first transistor for amplifying the oscillating signal.

12. The anti-theft structure as claimed in claim 11, wherein the power amplifying circuit includes a first transformer, a second transformer, and a second transistor, the high-voltage signal is coupled to a base of the second transistor through the first transformer, the second transformer is connected to a collector of the second transistor.
